(19) United States
(12) Patent Application Publication
(10) Pub. No.: US 2010/0167211 A1
(43) Pub. Date: Jul. 1, 2010

(54) METHOD FOR FORMING FINE PATTERNS IN A SEMICONDUCTOR DEVICE

(75) Inventors: Dong Seok KIM, Seoul (KR); Jin Yul LEE, Icheon-si (KR)

Correspondence Address: MARSHALL, GERSTEIN & BORUN LLP, 233 SOUTH WACKER DRIVE, 6300 WILLIS TOWER, CHICAGO, IL, 60606-6357, US

(73) Assignee: HYNIX SEMICONDUCTOR INC., Gyeonggi-do (KR)

(21) Appl. No.: 12/492,720

(22) Filed: Jun. 26, 2009

(30) Foreign Application Priority Data
Dec. 30, 2008 (KR) 10-2008-0136778

(51) Int. Cl. G03F 7/20

(52) U.S. Cl. 430/313; 430/319

(57) ABSTRACT

A method for forming fine patterns in a semiconductor device includes forming a first mask layer over an etch target layer, forming a first pattern over the first mask layer, reducing a size of the first pattern, forming a first spacer on a side face of the first pattern, removing the first pattern and patterning the first mask layer using the first spacer as a mask and removing the first spacer. The method also includes oxidating a surface of the patterned first mask layer, forming the first mask layer with reduced size by removing the oxidated portion over the surface of the first mask layer, forming a second spacer on a side wall of the first mask layer and removing the first mask layer, and patterning the etch target layer using the second spacer as a mask.

### CROSS-REFERENCE TO RELATED APPLICATION

The priority of Korean patent application No. 10-2008-0136778 filed on Dec. 30, 2008, the entire disclosure of which is incorporated by reference, is claimed.

### BACKGROUND OF THE INVENTION

1. Field of the Invention

The invention generally relates to a method for fabricating a semiconductor device and, more particularly, to a method for forming fine patterns in a semiconductor device using a spacer.

2. Brief Description of Related Technology

As semiconductor devices become more highly integrated, the required resolution becomes smaller than a minimum resolution that can be resolved using a photolithography apparatus. Various technologies for overcoming this limitation in the photolithography apparatus and to form ultra fine patterns have been suggested. One such technology is a patterning technology using a spacer.

The patterning technology using a spacer is a method capable of forming fine patterns corresponding to a thickness of a spacer, by forming a material layer pattern of a certain size over an etch target layer, forming the spacer around the material layer pattern and then etching the etch target layer under the spacer using the spacer as an etch mask. However, the conventional patterning method using a spacer represents a limitation and there is thus a need for an improved pattern-forming method capable of finally forming more lines and spaces within the same pitch while maintaining the same size of the pattern formed on the photomask.

### SUMMARY OF THE INVENTION

Embodiments of the invention are directed to a method for forming fine patterns in a semiconductor device capable of finally forming more lines and spaces within the same pitch while maintaining the same size of the pattern formed on the photomask.

In one embodiment, a method for forming fine patterns in a semiconductor device includes forming a hard mask layer over an etch target layer, forming a plurality of first patterns over the hard mask layer, reducing a size of the first patterns, forming first spacers on side walls of the first patterns, removing the first patterns, and patterning the hard mask layer using the first spacers as mask to form hard mask patterns and removing the first spacers. The method also includes oxidating a surface of the patterned hard mask layer, removing the oxidated portion over the surface of the hard mask layer, forming a second spacer on a side wall of the first mask layer and removing the first mask layer, and patterning the etch target layer using the second spacer as a mask.

Additional features of the disclosed invention may become apparent to those skilled in the art from a review of the following detailed description, taken in conjunction with the drawings, and the appended claims.

### BRIEF DESCRIPTION OF THE DRAWINGS

For a more complete understanding of the disclosure, reference should be made to the following detailed description and accompanying drawings wherein:

FIGS. 1 through 8 are cross-sectional views illustrating a method for forming fine patterns in a semiconductor device in accordance with an embodiment of the present invention.

While the disclosed method is susceptible of embodiments in various forms, there are illustrated in the drawings (and will hereafter be described) specific embodiments of the invention, with the understanding that the disclosure is intended to be illustrative, and is not intended to limit the invention to the specific embodiments described and illustrated herein.

### DESCRIPTION OF SPECIFIC EMBODIMENTS

Embodiments of the present invention provides a method for forming fine patterns capable of realizing more lines/spaces within the same pitch over a semiconductor substrate while maintaining the same size of patterns laid out over a photomask.

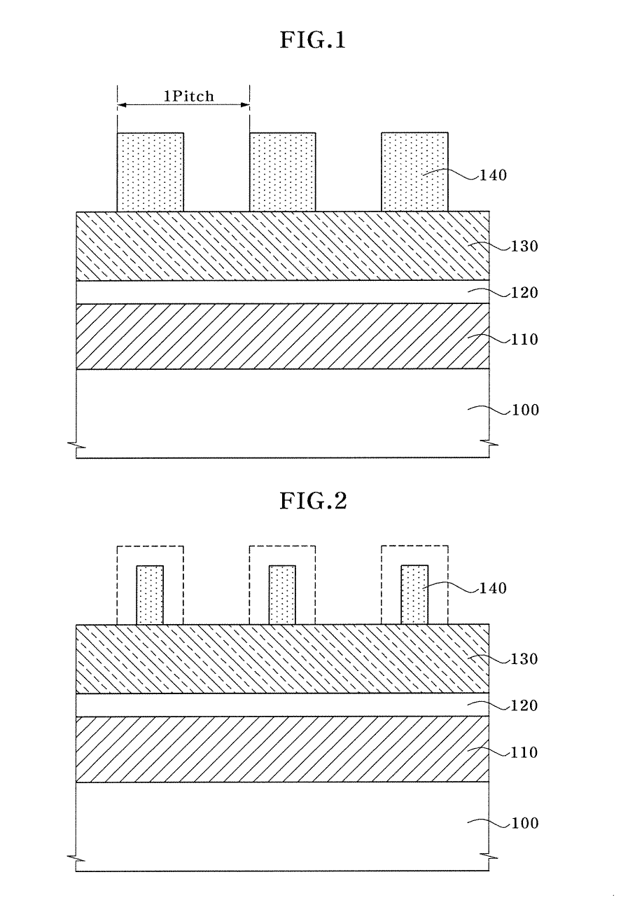

FIGS. 1 through 8 are cross-sectional views illustrating a method for forming fine patterns in a semiconductor device in accordance with an embodiment of the present invention.

FIG. 1 illustrates an etch target layer 110 to be patterned over a semiconductor substrate 100. The etch target layer 110 can be a single layer or a multi-layer in which two or more layers are stacked. In a case of a memory device, the etch target layer 110 can have a structure in that a gate conductive layer of a transistor formed, for example, of a polysilicon layer and a gate metal layer formed, for example, of tungsten suicide (WSi) are stacked.

A first mask layer 120 is formed over the etch target layer 110. The first mask layer 120 is to be used as a mask when patterning the etch target layer. The first mask layer 120 can be a single layer or a stacked layer of two or more layers for patterning the multi-layered etch target layer. A material for forming the first mask layer 120 can be varied based on the etch target layer. For example, when the etch target layer 110 includes a polysilicon layer as the gate conductive layer, the first mask layer 120 can be formed, as a gate hard mask, of oxide, nitride, amorphous carbon or silicon oxynitride (SiON). If necessary, the first mask layer 120 can be omitted.

A second mask layer 130 is formed over the first mask layer 120. The second mask layer 130 is for patterning the first mask layer to a finer size in a subsequent process, and includes a material having an etch selectivity to the first mask layer 120. For example, when the first mask layer 120 is formed of oxide, nitride, amorphous carbon, or silicon oxynitride (SiON), the second mask layer 130 can include metal, silicide, or polysilicon layer.

A first pattern 140 is formed over the second mask layer 130, preferably through a photolithography process. The first pattern 140 includes various materials such as oxide, nitride, amorphous carbon, and silicon oxynitride (SiON), and preferably includes a material having an etch selectivity to the material of the second mask layer 130. The first pattern 140 is formed with the same width as the pattern formed over a photomask (not shown) and has a first pitch.

Referring to FIG. 2, an isotropic etch is performed on the first pattern 140 to reduce the size of the first pattern. The isotropic etch on the first pattern 140 can be implemented by a dry etch using plasma or a wet etch using an etchant solution, and the etch process, the etchant gas or the etchant solution can be suitably selected according to the material of the first pattern 140.

Instead of implementing the isotropic etch for reducing the size of the first pattern 140, an oxidation or nitrification process and an oxide layer-or nitride layer-removal process, which will be performed later, can be performed. In other words, the surface of the first pattern 140 is oxidated or nitrified to a certain thickness and the oxide layer or the nitride layer over the surface of the first pattern 140 is removed with an oxide layer-or nitride layer-etchant, thereby capable of reducing the size of the first pattern 140.

Referring to FIG. 3, a spacer layer is formed over the product resulting from the isotropic etch on the first pattern 140. Since this spacer layer should remain in non-etched state while the first pattern is removed in the subsequent etch process on the first pattern 140, the spacer layer should include a layer having an etch selectivity to the first pattern 140. A thickness of the spacer layer is determined based on the size of the first pattern 140 and a size of a hard mask pattern to be formed in a subsequent process.

Next, an anisotropic etch is performed on the spacer layer to form a spacer 150 on a side wall of the first pattern 140. The anisotropic etch on the spacer layer can be implemented, for example, by a dry etch using plasma. A thickness of the spacer 150 is determined based on the size of the first pattern 140 and a size of a second mask layer pattern 130a.

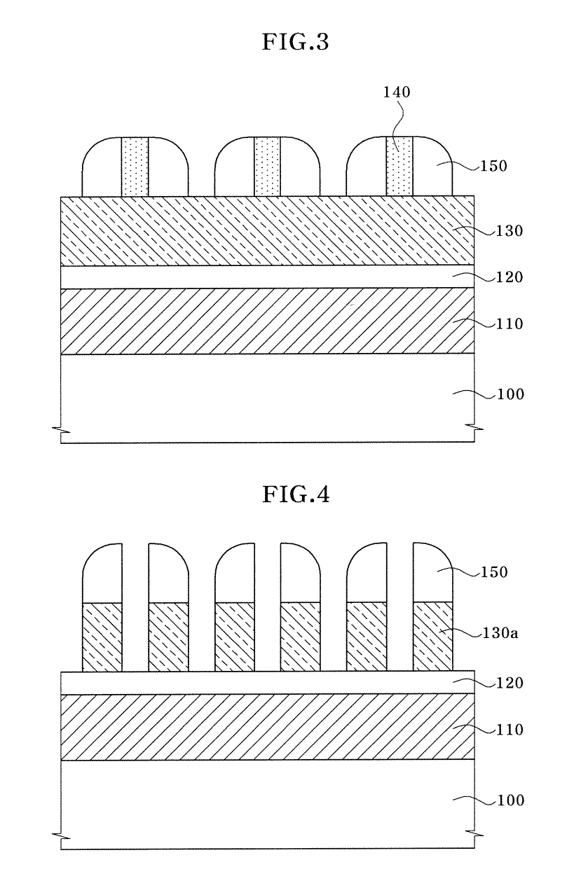

Referring to FIG. 4, the first patterns remaining between the spacers are removed to leave the spacer 150 alone. At this time, the first pattern can be removed using plasma or an etchant solution, and the etch process, the etchant gas or the etchant solution can be selected based on a material of the first pattern and a material of the spacer. The exposed portion of the second mask layer is etched using the spacer, remaining after the first pattern is removed, as an etch mask to form the second mask layer pattern 130a.

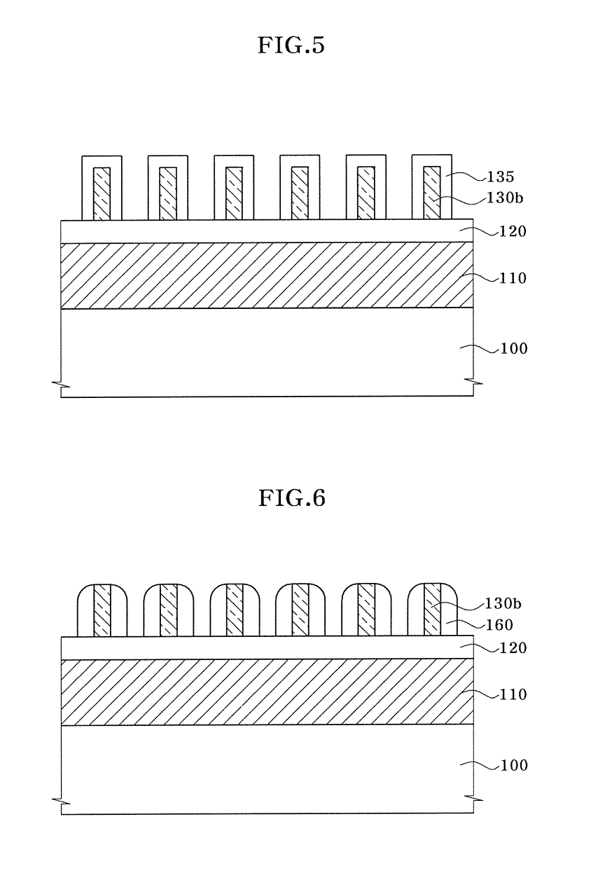

Referring to FIG. 5, the spacer 150 is removed and the surface of the second mask layer pattern 130a is then oxidated to a certain thickness to reduce the size of the second mask layer pattern 130a. Then, as shown, an oxide layer 135 is formed on an upper portion and a side surface of the second mask layer pattern 130b. Alternatively, instead of oxidating the surface of the second mask layer pattern, it is possible to nitrify the surface of the second mask layer pattern under an atmosphere containing a nitrogen gas to form a nitride layer. Because a patterning space of the final etch target layer is determined by the second mask layer pattern 130b, remaining after the oxide layer 135 or the nitride layer is removed, the thickness of the oxide layer 135 or the nitride layer is determined according to the space of the patterns to be finally realized.

Referring to FIG. 6, the oxide layer formed over the surface of the second mask layer pattern 130b is removed. At this time, a wet etch can be used. Consequently, the size of the second mask layer pattern 130b is reduced by the thickness of the removed oxide layer.

Next, a spacer 160 is formed on the side wall of the second mask layer pattern 130b. This spacer 160 can be formed of a material that is not etched when the second mask layer pattern 130b is removed, i.e. a layer having an etch selectivity. A thickness of the spacer 160 can be determined based on a size of the etch target layer to be finally formed.

FIG. 7 illustrates the second mask layer pattern remaining between the spacers 160. At this time, a dry etch using plasma or a wet etch using a wet chemical can be used. Then, the spacer 160 alone remains over the first mask layer 120. The thickness of the spacer 160 becomes the width of the pattern to be finally realized, and the space between the spaces 160 becomes the space between the patterns.

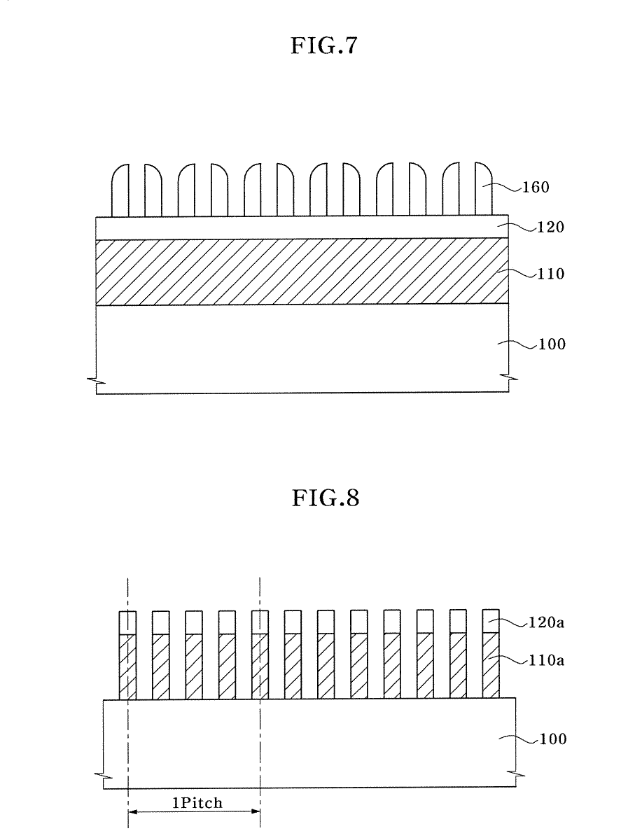

Referring to FIG. 8, the exposed portion of the first mask layer is etched using the spacer as an etch mask. The spacer is removed and the etch target layer is then patterned, using the patterned first mask layer 120a as a mask, to finally form a desired target layer pattern 110a. The target layer pattern 110a has the same width as the width of the spacer and is formed at the same space as the space between the spacers. As compared to the first pattern 140, which has the same size as the pattern over the first photomask shown in FIG. 1, it can be appreciated that four patterns and spaces are realized within the same pitch. In other words, the pattern density is increased by four times.

As is apparent from the above description, in accordance with a method for forming fine patterns in a semiconductor device of the present invention, it is possible to finally realize more lines and spaces over a semiconductor substrate within the same pitch while maintaining the same size of the pattern over the photomask.

While the present invention has been described with respect to the specific embodiments, it will be apparent to those skilled in the art that various changes and modifications may be made without departing from the spirit and scope of the invention as defined in the following claims.

What is claimed is:

1. A method for forming fine patterns in a semiconductor device, the method comprising:
forming a hard mask layer over an etch target layer;
forming a plurality of first patterns with a predetermined width and space over the hard mask layer;
reducing size of the first patterns;
forming first spacers on side walls of the first patterns and removing the first patterns;
patterning the hard mask layer using the first spacers as mask to form a hard mask patterns and removing the first spacers;
oxidating surfaces of the hard mask patterns;
removing the oxidated portion over the surfaces of the hard mask patterns;
forming second spacers on side walls of the hard mask patterns and removing the hard mask patterns; and,
patterning the etch target layer using the second spacers as mask.

2. The method of claim 1, wherein the etch target layer comprises a single layer or a multi-layer.

3. The method of claim 1, wherein the first pattern comprises a material having an etch selectivity to the hard mask layer.

4. The method of claim 3, wherein the hard mask layer comprises a polysilicon layer, a metal layer, or a silicide, and
the first pattern comprises a material selected from the group consisting of oxide, nitride, amorphous carbon, and silicon oxynitride (SiON).

5. The method of claim 1, wherein the reducing the size of the first pattern comprises isotropic etching the first pattern.

6. The method of claim 5, wherein the isotropic etching comprises dry etching using plasma, or wet etching using a chemical.

7. The method of claim 1, wherein the reducing the size of the first pattern comprises:
oxidating a surface of the first pattern; and,
removing the oxidated portion of the first pattern.

8. The method of claim 1, wherein the reducing the size of the first pattern comprises
nitrifying a surface of the first pattern; and,
removing the nitrified portion of the first pattern.

9. The method of claim 1, wherein the first spacer comprises a material having an etch selectivity to the first pattern and the hard mask layer.

10. The method of claim 1, wherein the second spacer comprises a material having an etch selectivity to the first pattern and the etch target layer.
